(19) United States
(12) Patent Application Publication
(10) Pub. No.: US 2018/0108746 A1
(43) Pub. Date: Apr. 19, 2018

(54) THIN FILM TRANSISTORS (TFTS), MANUFACTURING METHODS OF TFTS, AND CMOS COMPONENTS

(71) Applicant: Shenzhen China Star Optoelectronics Technology Co., Ltd., Shenzhen, Guangdong (CN)

(72) Inventors: Fenli ZHAO, Shenzhen, Guangdong (CN); Yingtao XIE, Shenzhen, Guangdong (CN)

(73) Assignee: Shenzhen China Star Optoelectronics Technology Co., Ltd., Shenzhen, Guangdong (CN)

(21) Appl. No.: 15/112,638

(22) PCT Filed: Jun. 21, 2016
(86) PCT No.: PCT/CN2016/086639

§ 371 Date: Jul. 19, 2016

(30) Foreign Application Priority Data
May 26, 2016 (CN) 201610363860.0

(51) Int. Cl. H01L 29/423; H01L 29/786; H01L 29/66; H01L 21/28; H01L 21/265; H01L 21/266; H01L 27/12

(52) U.S. Cl. CPC H01L 29/42384; H01L 29/78675; H01L 29/78621; H01L 29/66757; H01L 21/28158; H01L 2029/42388; H01L 21/266; H01L 21/28123; H01L 27/1222; H01L 27/1237; H01L 21/26513

(57) ABSTRACT

The present disclosure relates to a TFT, a manufacturing method of TFTs, and a CMOS component. The TFT includes a substrate, a LTPS layer arranged close to the substrate, a first light doping area and a second light doping area on the same layer with the LTPS layer and arranged at two opposite ends of the LTPS layer, a first heavy doping area and a second heavy doping area arranged at the same layer with the LTPS layer, a first insulation layer having a first portion and a second portion, and a gate arranged on the second portion. The first heavy doping area is arranged on one end of the first light doping area farther away from the LTPS layer, and the second heavy doping area is arranged on one end of the second light doping area farther away from the LTPS layer.

### CROSS REFERENCE

This application claims the priority of Chinese Patent Application No. 201610363860.0, entitled “Thin film transistors (TFTs), manufacturing methods of TFTs, and CMOS components”, filed on May 26, 2016, the disclosure of which is incorporated herein by reference in its entirety.

### FIELD OF THE INVENTION

The present invention relates to display technology field, and more particularly to a TFT, a manufacturing method of TFTs, and a CMOS component.

### BACKGROUND OF THE INVENTION

Liquid crystal display (LCD) is a very common electronic device, characterized by low power consumption, small dimension, and light weight, and thus has been favored by consumers. With the development of the flat display technology, the demand toward high resolution and low power consumption LCD has been proposed. The electron mobility rate of amorphous silicon is low, however, low temperature poly-silicon (LTPS) may be manufacture at a low temperature, and it also includes a higher carrier mobility rate than the amorphous silicon. Second, the CMOS components manufactured by may be incorporated by the LCDs so as to obtain higher resolution and lower power consumption. Thus, LTPS has been widely adopted and researched. The higher carrier mobility rate may cause hot carrier effects, which may result in a drifting threshold voltage (Vth) of the LTPS TFTs or Kink issue. To avoid the hot carrier effect, generally, the ion injection method is adopted to form shallow doping transition area, such as light doped drain (LDD) and gate on LDD (GOLDD). The shallow doping transition area is formed by mask processes or formed by gate self-alignment doping. However, the number of the masks involved is large, and the doping bias or the gate may deviate from the LDD area may occur with respect to the LTPS TFTs. As such, the performance of the LTPS TFTs is bad.

### SUMMARY OF THE INVENTION

In one aspect, a thin film transistor (TFT) includes: a substrate; a low temperature poly-silicon (LTPS) layer arranged close to the substrate; a first light doping area and a second light doping area arranged on the same layer with the LTPS layer, and are arranged at two opposite ends of the LTPS layer, doping concentrations of symmetrical portions of the first light doping area and the with respect to the LTPS layer are the same; a first heavy doping area and a second heavy doping area are arranged at the same layer with the LTPS layer, the first heavy doping area is arranged on one end of the first light doping area farther away from the LTPS layer, the doping concentrations of symmetrical portions of the first heavy doping area and the second heavy doping area with respect to the LTPS layer are the same, the second heavy doping area is arranged on one end of the second light doping area farther away from the LTPS layer, doping types of the first light doping area, the second light doping area, the first heavy doping area, and the second heavy doping area are the same; a first insulation layer includes a first portion and a second portion, the first portion covers the LTPS layer, the first light doping area, the second light doping area, the first heavy doping area, and the second heavy doping area, the second portion is arranged in a middle portion of a surface of the LTPS layer facing away the LTPS layer, and the second portion and the first portion cooperatively form a “ [symbol] ”-shaped structure; and a gate is arranged on the second portion, and the gate contacts with the second portion, the gaps respectively between two end surfaces of the gate and a middle point of the LTPS layer are the same.

Wherein the first light doping area contacts with the LTPS layer via a first plane, and the second light doping area contacts with the LTPS layer via a second plane, the second heavy doping area is arranged on one end of the second light doping area facing away the LTPS layer, the second portion includes a first end surface and a second end surface opposite to the first end surface, the first end surface and the second end surface respectively contacts with the surfaces of the first portion close to the second portion, the first end surface and the first plane are on the same plane, and the second end surface and the second plane are on the same plane.

Wherein the first portion includes a first through hole corresponding to the first heavy doping area, and a second through hole corresponding to the second heavy doping area, the TFT further includes: a second insulation layer covers the gate, and the second insulation layer includes a third through hole and a fourth through hole, the third through hole communicates with the first through hole, and the fourth through hole communicates with the second through hole; a source and a drain arranged on the second insulation layer, and the source connects to the first heavy doping area via the first through hole and the third through hole, the drain connects to the second heavy doping area via the second through hole and the fourth through hole; and a flat layer covers the source and the drain.

Wherein the flat layer includes a fifth through hole corresponding to the drain, the TFT further includes a pixel electrode arranged on the flat layer, and the pixel electrode connects to the drain via the fifth through hole.

Wherein doping types of the first light doping area, the second light doping area, the first heavy doping area, and the second heavy doping area are N-type ion doping or P-type ion doping.

In another aspect, a manufacturing method of TFTs includes: providing a substrate; forming a polysilicon layer on the substrate and patterning the polysilicon layer to form a LTPS pattern; forming a gate insulation layer, a first metal layer, and a photo-resist layer on a surface of the LTPS pattern facing away the substrate in sequence; patterning the first photo-resist layer to reserve a first photo-resist pattern corresponding to the LTPS pattern, the first photo-resist pattern includes a first surface and a second surface opposite to the first surface, the first surface and the second surface contact with a surface of the first metal layer close to the photo-resist layer, the first surface and the second surface are between two opposite planes of the LTPS pattern contacting with the substrate; applying the patterning process to the first metal layer to remove the first metal layer uncovered by the first photo-resist pattern, to reserve the first metal layer covered by the first photo-resist pattern, and to etch a portion of the gate insulation layer to reserve the first insulation layer corresponding to the LTPS pattern, the first insulation layer includes a first portion and a second portion, the first portion covers the LTPS pattern, the second portion is arranged in a middle portion of the surface of the first portion facing away the LTPS layer, and the second portion and the first portion cooperatively form a “ [symbol] ”-shaped structure, the two opposite end surfaces of the second portion are on the same plane respectively with the first surface and the second surface; applying an ashing process to two ends of the first photo-resist pattern; applying an etching process to the first metal layer to remove two ends of the ashed areas of the first photo-resist pattern corresponding to the first metal layer, and the reserved first metal layer is formed to be the gate; adopting the first photo-resist pattern and the first insulation layer as masks to perform an ion doping process to the LTPS pattern, the LTPS pattern corresponding to the first photo-resist pattern is formed to be the LTPS layer, which is only covered by the first portion and the second portion, the portion of the LTPS layer uncovered by the first photo-resist pattern is formed to be the first light doping area and the second light doping area, the LTPS pattern only covered by the first portion is formed to be the first heavy doping area and the second heavy doping area; applying the etching process to the first insulation layer to remove the portion of the second portion uncovered by the gate; and stripping the first photo-resist pattern.

Wherein the method further includes: depositing a second insulation layer on the gate and the first insulation layer; configuring through holes on the second insulation layer and the first insulation layer, and the through holes correspond to the first heavy doping area and the second heavy doping area, the first through hole corresponding to the first heavy doping area and the second through hole corresponding to the second heavy doping area are formed on the first insulation layer, and the third through hole communicating with the first through hole and the fourth through hole communicating with the second through hole are formed on the second insulation layer; depositing a second metal layer on the second insulation layer to pattern the second metal layer so as to form a source connecting to the first heavy doping area via the first through hole and the third through hole, and to form a drain connecting to the second heavy doping area via the second through hole and the fourth through hole; and depositing a flat layer on the source and the drain.

Wherein the ion doping are of N-type ion doping or P-type ion doping.

Wherein when the first photo-resist pattern and the first insulation layer are adopted as the masks to perform the ion doping process toward the LTPS pattern, the doping concentrations of the first portion, the second portion, and the first photo-resist pattern are the same, and the doping time are the same.

In another aspect, a CMOS component includes the above TFT.

In view of the above, the first photo-resist pattern and the first insulation layer are adopted as masks. The doping concentration of each portions of the LTPS pattern may be different due to the thickness of the first portion and the second portion. That is, the LTPS pattern corresponding to the first photo-resist pattern is the LTPS layer. The LTPS pattern only covered by the first portion and the second portion and uncovered by the first photo-resist pattern forms the first light doping area and the second light doping area. The LTPS pattern covered by the first portion is formed to be the first heavy doping area and the second heavy doping area. The masking process may be excluded so as to simplify the manufacturing process of the TFTs.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a cross section view of the TFT in accordance with one embodiment.

FIG. 2 is a circuit diagram of the CMOS component in accordance with one embodiment.

FIG. 3 is a cross section view of the CMOS component in accordance with one embodiment.

FIG. 4 is a flowchart of the manufacturing method of the TFTs in accordance with one embodiment.

FIGS. 5-14 are schematic views corresponding to the steps of the manufacturing method of the TFTs in accordance with one embodiment.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

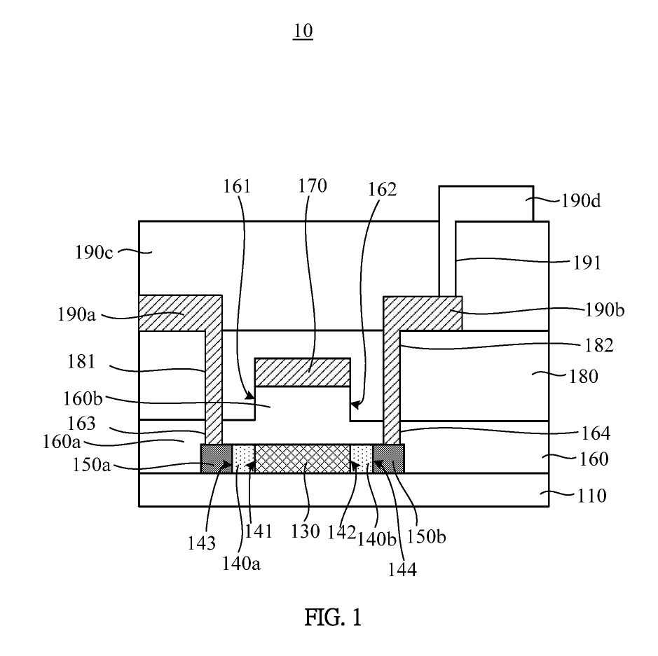

FIG. 1 is a cross section view of the TFT in accordance with one embodiment. The TFT 10 includes a substrate 110, a LTPS layer 130, a first light doping area 140a, a second light doping area 140b, a first heavy doping area 150a, a second heavy doping area 150b, a first insulation layer 160, and a gate 170. The LTPS layer 130 is arranged to be close to the substrate 110. It can be understood that the LTPS layer 130 may be directly formed on a surface of the substrate 110, also may be arranged on the substrate 110 via a buffer layer. The first light doping area 140a, the second light doping area 140b, and the LTPS layer 130 are arranged at the same layer, and the first light doping area 140a and the second light doping area 140b are arranged at two opposite ends of the LTPS layer 130. Doping concentrations of the symmetrical portions of the first light doping area 140a and the second light doping area 140b with respect to the LTPS layer 130 are the same. The first heavy doping area 150a, the second heavy doping area 150b, and the LTPS layer 130 are arranged at the same layer. The first heavy doping area 150a is arranged on one end of the first light doping area 140a farther away from the LTPS layer 130, and the doping concentrations of the symmetrical portions of the first heavy doping area 150a and the second heavy doping area 150b with respect to the LTPS layer 130 are the same. The doping types of the first light doping area 140a, the second light doping area 140b, the first heavy doping area 150a, and the second heavy doping area 150b are the same. The first insulation layer 160 includes a first portion 160a and a second portion 160b. The first portion 160a covers the LTPS layer 130, the first light doping area 140a, the second light doping area 140b, the first heavy doping area 150a, and the second heavy doping area 150b. The second portion 160b is arranged in a middle portion of the surface of the LTPS layer 130 facing away the LTPS layer 130, and the second portion 160b and the first portion 160a cooperatively form a “ [symbol] ”-shaped structure. The gate 170 is arranged on the second portion 160b, and the gate 170 contacts with the second portion 160b. The gaps respectively between the two end surfaces of the gate 170 and a middle point of the LTPS layer are the same.

The substrate 110 may be made by any one of or a plurality of electrical insulation materials, including quartz, mica, aluminum oxide, or transparent plastics. The substrate 110 is an insulation substrate to reduce the high-frequency loss of the substrate 110.

The LTPS layer 130, the first light doping area 140a, the second light doping area 140b, the first heavy doping area 150a, the second heavy doping area 150b, the first insulation layer 160, and the gate 170 are arranged on the same side of the substrate 110. It can be understood that the first light doping area 140a, the second light doping area 140b, the first heavy doping area 150a, the second heavy doping area 150b, the first insulation layer 160, and the gate 170 may be directly or indirectly arranged on the same side of the substrate 110. In one embodiment, the first light doping area 140a, the second light doping area 140b, the first heavy doping area 150a, the second heavy doping area 150b, the first insulation layer 160, and the gate 170 are arranged on the same of the substrate 110 via a buffer layer to reduce the damages toward the substrate 110 in the manufacturing process of the TFT 10.

The first light doping area 140a contacts with the LTPS layer 130 via a first plane 141, and the second light doping area 140b contacts with the LTPS layer 130 via a second plane 142. The first heavy doping area 150a contacts with the first light doping area 140a via a third plane 143. The second heavy doping area 150b is arranged on one end of the second light doping area 140b facing away the LTPS layer 130. The second heavy doping area 150b contacts with the second light doping area 140b via a fourth plane 144. The second portion 160b includes a first end surface 161 and a second end surface 162 opposite to the first end surface 161. The first end surface 161 and the second end surface 162 respectively contacts with the surfaces of the first portion 160a close to the second portion 160b. The first end surface 161 and the first plane 141 are on the same plane, and the second end surface 162 and the second plane 142 are on the same plane.

The first portion 160a includes a first through hole 163 corresponding to the first heavy doping area 150a, and a second through hole 164 corresponding to the second heavy doping area 150b. Correspondingly, the TFT further includes a second insulation layer 180, a source 190a, a drain 190b, and a flat layer 190c. The second insulation layer 180 covers the gate 170, and the second insulation layer 180 includes a third through hole 181 and a fourth through hole 182. The third through hole 181 communicates with the first through hole 163, and the fourth through hole 182 communicates with the second through hole 164. The source 190a and the drain 190b are arranged on the second insulation layer 180, and the source 190a connects to the first heavy doping area 150a via the first through hole 163 and the third through hole 181. The drain 190b connects to the second heavy doping area 150b via the second through hole 164 and the fourth through hole 182. The flat layer 190c covers the source 190a and the drain 190b.

The flat layer 190c includes a fifth through hole 191 corresponding to the drain 190b. The TFT 10 further includes a pixel electrode 190d arranged on the flat layer 190c, and the pixel electrode 190d connects to the drain 190b via the fifth through hole 191.

The doping types of the first light doping area 140a, the second light doping area 140b, the first heavy doping area 150a, and the second heavy doping area 150b are the same, such as are of N-type ion doping or P-type ion doping. The N-type ion doping may include, but not limited to phosphorus (P) ions, and arsenic (AS) ions. The P-type ion doping may be, but not limited to, boron (B) ions.

The doping concentration of the first heavy doping area 150a is greater than the doping concentration of the first light doping area 140a, and the doping concentration of the second heavy doping area 150b is greater than the doping concentration of the second light doping area 140b. As such, not only the contact resistance between the source 190a and the LTPS layer 130 may be reduced, but also the contact resistance between the drain 190b and the LTPS layer 130 may be reduced. Further, the leaking current of the TFT 10 may be decreased.

The first insulation layer 160 includes, but not limited to, SiNx and SiOx.

The gate 170 may be made by one or a plurality of metallic materials including, but not limited to, Al, Mo, Cu, Ag, Cr, Ti, AlNi, and MoTi. The thickness of the gate 170 is in a range from 1500 to 6000 angstroms.

The second insulation layer 180 may include, but not limited to, SiNx and SiOx.

The source 190a and the drain 190b may be made by one or a plurality of metallic materials including, but not limited to, Al, Mo, Cu, Ag, Cr, Ti, AlNi, and MoTi.

The pixel electrode 190d may be made by one or a plurality of metallic materials including, but not limited to, ZnO, SnO₂, and In₂O₃. For instance, the transparent oxide semiconductor film layer may be Indium Gallium Zinc Oxide (IGZO).

In view of the above, the first light doping area 140a and the second light doping area 140b of the TFT 10 are arranged at the same layer with the LTPS layer 130, and the first light doping area 140a and the second light doping area 140b are arranged at two opposite ends of the LTPS layer 130. The doping concentrations of symmetrical portions of the first light doping area 140a and the second light doping area 140b with respect to the LTPS layer 130 are the same. The first heavy doping area 150a, the second heavy doping area 150b, and the LTPS layer 130 are arranged at the same layer. The first heavy doping area 150a is arranged on one end of the first light doping area 140a farther away from the LTPS layer 130, and the doping concentrations of the symmetrical portions of the first heavy doping area 150a and the second heavy doping area 150b with respect to the LTPS layer 130 are the same. The doping types of the first light doping area 140a, the second light doping area 140b, the first heavy doping area 150a, and the second heavy doping area 150b are the same. The first insulation layer 160 includes a first portion 160a and a second portion 160b. The first portion 160a covers the LTPS layer 130, the first light doping area 140a, the second light doping area 140b, the first heavy doping area 150a, and the second heavy doping area 150b.

The second portion 160b is arranged in a middle portion of the surface of the LTPS layer 130 facing away the LTPS layer 130, and the second portion 160b and the first portion 160a cooperatively form a “ [symbol] ”-shaped structure. The gate 170 is arranged on the second portion 160b, and the gate 170 contacts with the second portion 160b. The gaps respectively between the two end surfaces of the gate 170 and a middle point of the LTPS layer are the same, such that the threshold voltage of the TFT 10 may be more stable, and the electric characteristics of the TFT 10 may be enhanced.

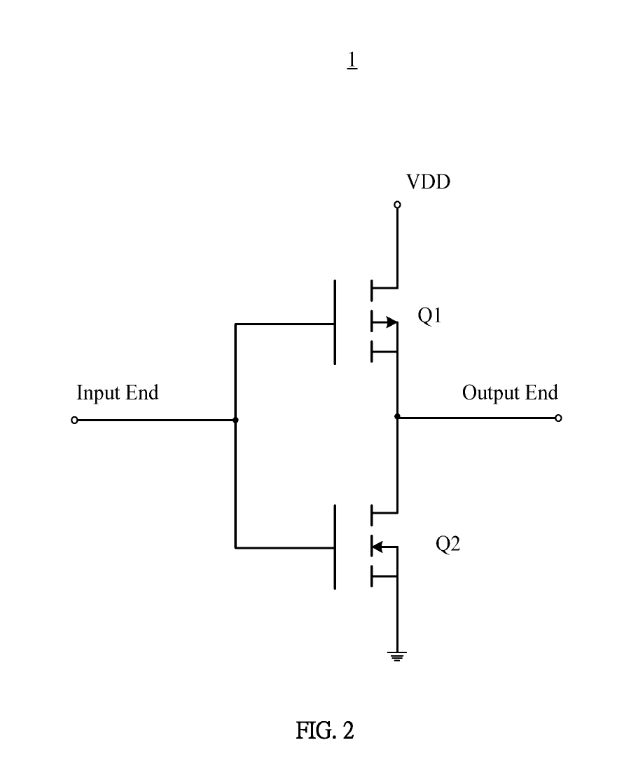

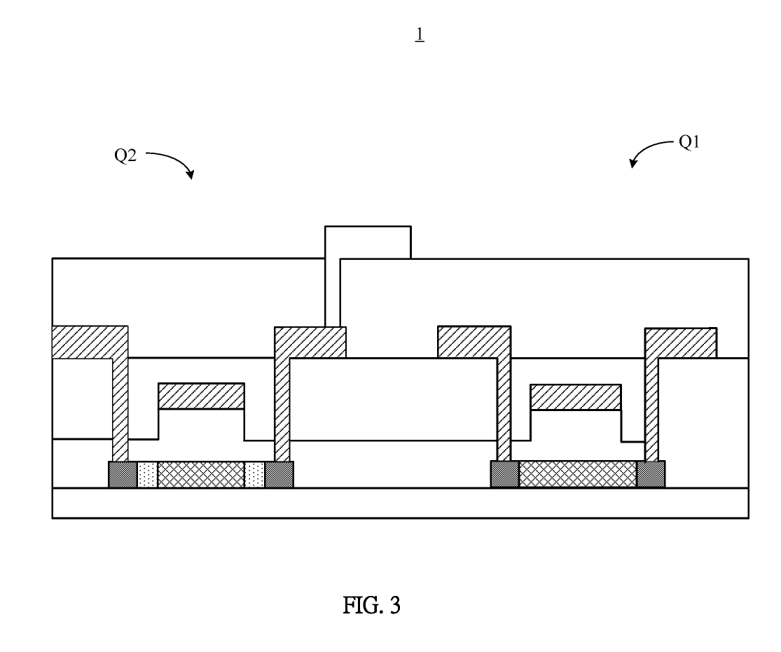

In one embodiment, referring to FIGS. 2 and 3, a Complementary Metal Oxide Semiconductor (CMOS) component 1 is provided. FIG. 2 is a circuit diagram of the CMOS component in accordance with one embodiment. FIG. 3 is a cross section view of the CMOS component in accordance with one embodiment. The CMOS component 1 includes a first TFT (Q1) and a second TFT (Q2), wherein when the first TFT (Q1) is a N-type TFT, the second TFT (Q2) is a P-type TFT. When the first TFT (Q1) is the P-type TFT, the second TFT (Q2) is the N-type TFT. A gate of the first TFT (Q1) electrically connects to the gate of the second TFT (Q2), and a drain of the first TFT (Q1) electrically connects to a source of the first TFT (Q1). The first TFT (Q1) of the CMOS component 1 may be the above TFT 10, or the second TFT (Q2) may of the CMOS component 1 may be the above TFT 10.

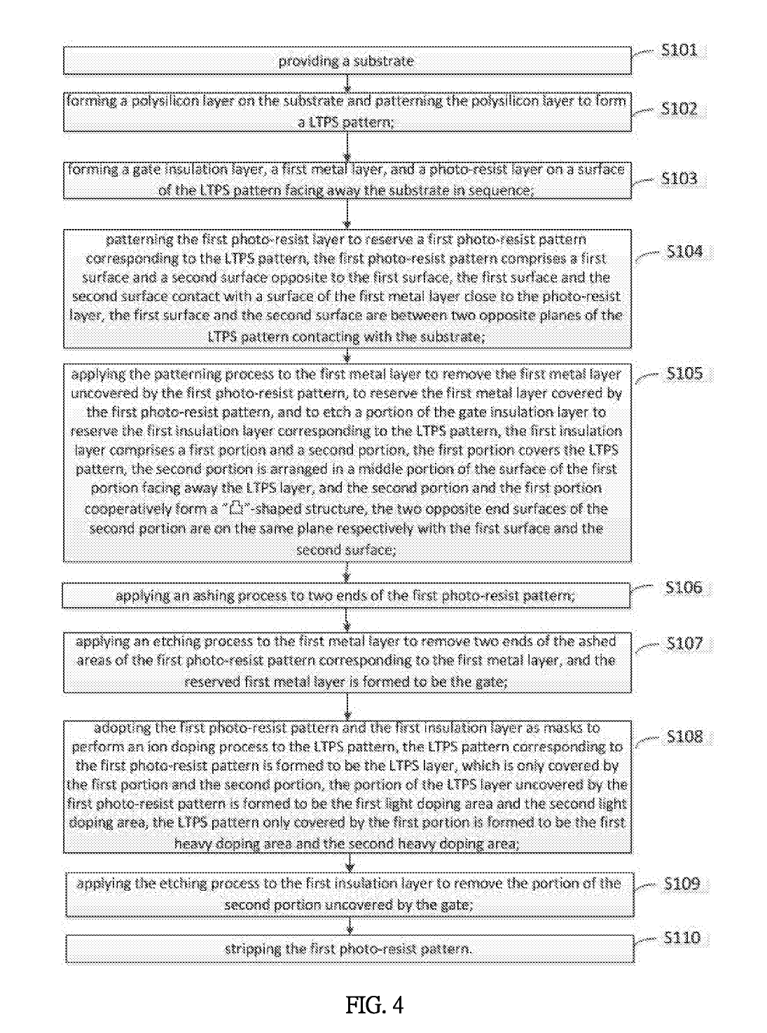

The manufacturing method of the TFT will be described with reference to FIG. 1 and the disclosure relating to the TFT 10. FIG. 4 is a flowchart of the manufacturing method of the TFTs in accordance with one embodiment. The manufacturing method may include, but not limited to, the steps below.

In step S101, providing a substrate 110. The substrate 110 may be made by any one of or a plurality of electrical insulation materials, including quartz, mica, aluminum oxide, or transparent plastics. The substrate 110 is an insulation substrate to reduce the high-frequency loss of the substrate 110.

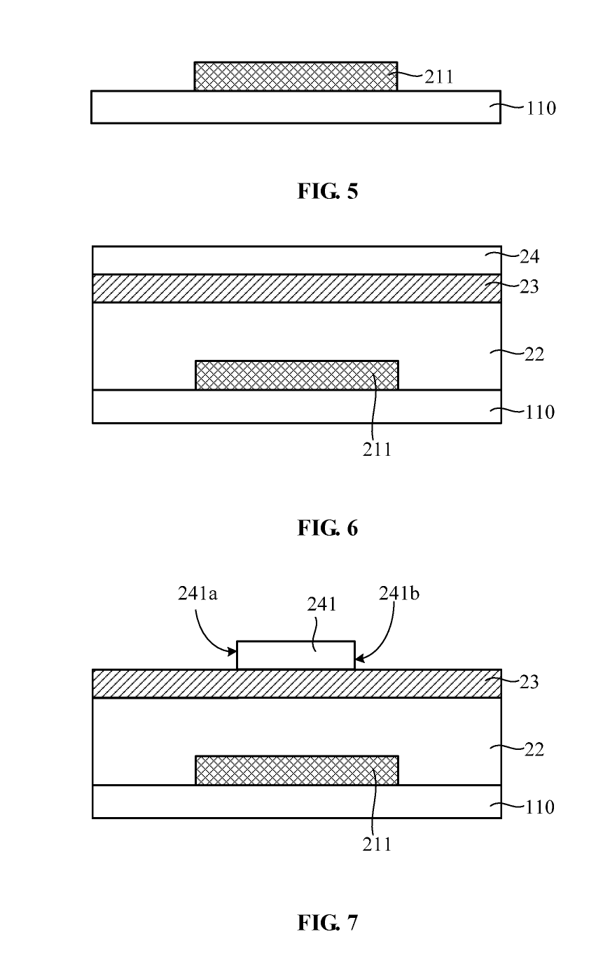

In step S102, forming a polysilicon layer on the substrate 110 and patterning the polysilicon layer to form a LTPS pattern 211. Referring to FIG. 5, in other embodiments, an a-Si layer may be formed on the substrate 110, and an excimer laser anneal process or other processes may be applied to the a-Si layer to transform the a-Si within the a-Si layer into polysilicon.

In step S103, forming a gate insulation layer 22, a first metal layer 23, and a first photo-resist layer 24 on the surface of the LTPS pattern 211 facing away the substrate 110 in sequence, please also refer to FIG. 6.

In step S104, applying a patterning process to the first photo-resist layer 24 to reserve the first photo-resist pattern 241 corresponding to the LTPS pattern 211. The first photo-resist pattern 241 includes a first surface 241a and a second surface 241b opposite to the first surface 241a. The first surface 241a and the second surface 241b contact with the surface of the first metal layer 23 close to the photo-resist layer 24. The first surface 241a and the second surface 241b are between two opposite planes of the LTPS pattern 211 contacting with the substrate (referring to FIG. 7).

In step S105, applying the patterning process to the first metal layer 23 to remove the first metal layer 23 uncovered by the first photo-resist pattern 241, to reserve the first metal layer 23 covered by the first photo-resist pattern 241, and to etch a portion of the gate insulation layer 22 to reserve the first insulation layer 160 corresponding to the LTPS pattern 211. The first insulation layer 160 includes a first portion 160a and a second portion 160b. The first portion 160a covers the LTPS pattern 211. The second portion 160b is arranged in a middle portion of the surface of the first portion 160a facing away the LTPS layer 130, and the second portion 160b and the first portion 160a cooperatively form a “ [symbol] ”-shaped structure. The two opposite end surfaces of the second portion 160b are on the same plane respectively with the first surface 241a and the second surface 241b (referring to FIG. 8).

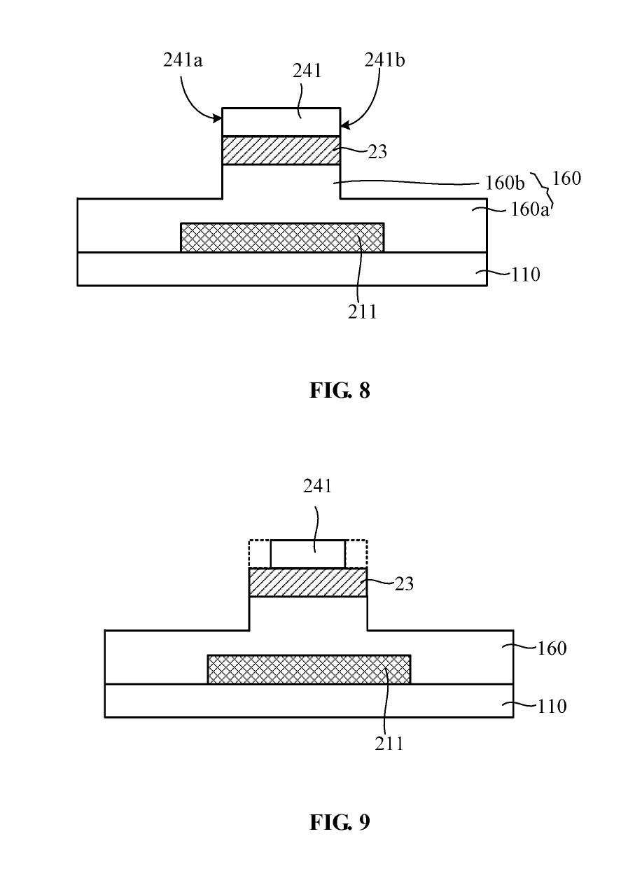

In step S106, applying an ashing process to two ends of the first photo-resist pattern 241. In the embodiment, the two ashed areas of the first photo-resist pattern 241 respectively correspond to the first light doping area 140a and the second light doping area 140b of the TFT 10 (referring to FIG. 9).

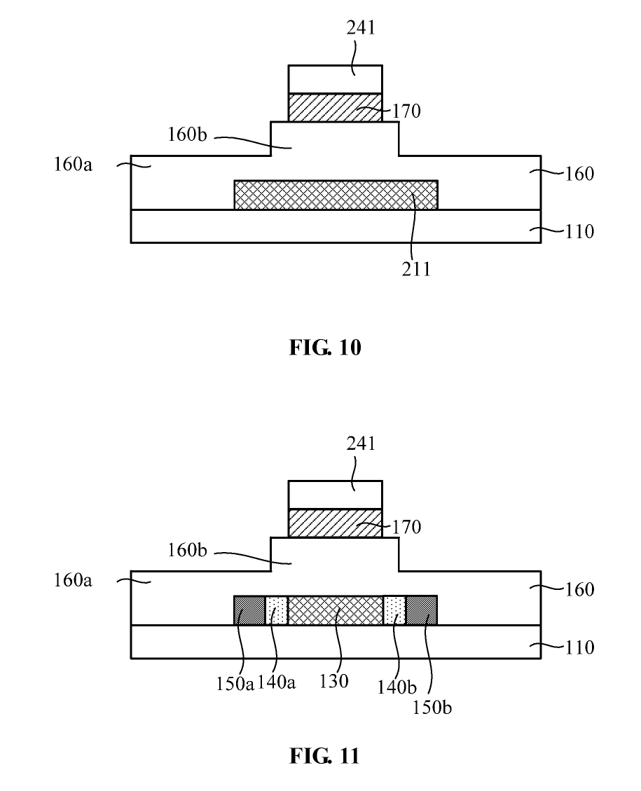

In step S107, applying an etching process to the first metal layer 23 to remove two ends of the ashed areas of the first photo-resist pattern 241 corresponding to the first metal layer 23, and the reserved first metal layer 23 is formed to be the gate 170 (referring to FIG. 10).

In step S108, adopting the first photo-resist pattern 241 and the first insulation layer 160 as masks to perform an ion doping process to the LTPS pattern 211. The LTPS pattern 211 corresponding to the first photo-resist pattern 241 is formed to be the LTPS layer 130, which is only covered by the first portion 160a and the second portion 160b. The portion of the LTPS layer 130 uncovered by the first photo-resist pattern 241 is formed to be the first light doping area 140a and the second light doping area 140b. The LTPS pattern 211 only covered by the first portion 160a is formed to be the first heavy doping area 150a and the second heavy doping area 150b. In the embodiment, when the first photo-resist pattern 241 and the first insulation layer 160 are adopted as the masks to perform the ion doping process toward the LTPS pattern 211, the doping concentrations of the first portion 160a, the second portion 160b, and the first photo-resist pattern 241 are the same (referring to FIG. 11).

In view of the above, the first photo-resist pattern 241 and the first insulation layer 160 are adopted as the masks. The doping concentration of each portions of the LTPS pattern 211 may be different due to the thickness of the first portion 160a and the second portion 160b. That is, the LTPS pattern 211 corresponding to the first photo-resist pattern 241 is the LTPS pattern 211. The LTPS pattern 211 covered by the first portion 160a and the second portion 160b, but uncovered by the first photo-resist pattern 241, is formed to be the first light doping area 140a and the second light doping area 140b. The LTPS pattern 211 covered by the first portion 160a is formed to be the first heavy doping area 150a and the second heavy doping area 150b. In this step, the masking process may be excluded so as to simplify the manufacturing process of the TFTs.

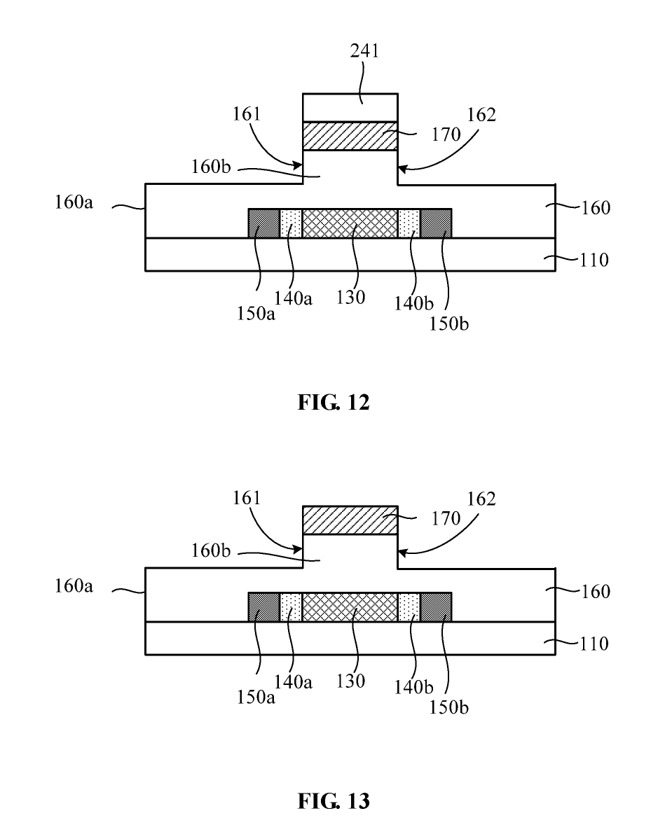

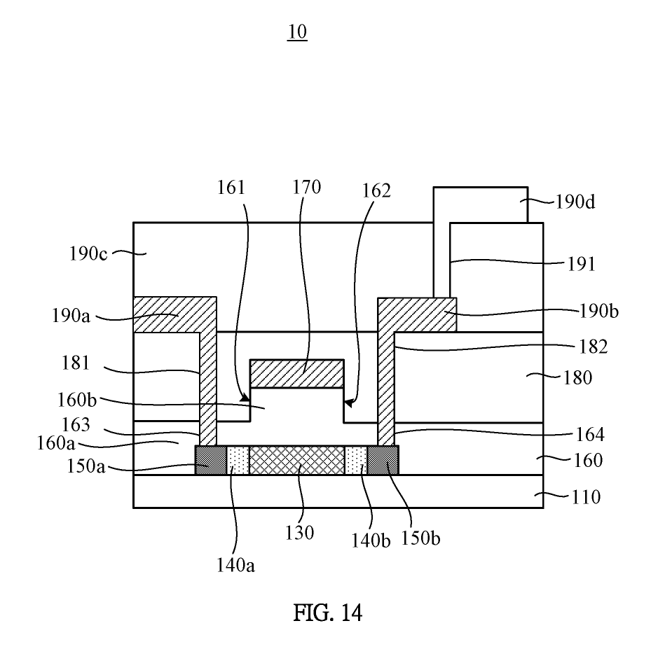

In step S109, applying the etching process to the first insulation layer 160 to remove the portion of the second portion 160b uncovered by the gate 170 (referring to FIG. 12).

In step S110, stripping the first photo-resist pattern 241 (referring to FIG. 13).

The manufacturing method of the TFTs may include the steps below.

In step S111, depositing the second insulation layer 180 on the gate 170 and the first insulation layer 160.

In step S112, configuring through holes on the second insulation layer 180 and the first insulation layer 160, and the through holes correspond to the first heavy doping area 150a and the second heavy doping area 150b. As such, the first through hole 163 corresponding to the first heavy doping area 150a and the second through hole 164 corresponding to the second heavy doping area 150b are formed on the first insulation layer 160, and the third through hole 181 communicating with the first through hole 163 and the fourth through hole 182 communicating with the second through hole 164 are formed on the second insulation layer 180.

In step S113, depositing a second metal layer 25 on the second insulation layer 180 to pattern the second metal layer 25 so as to form the source 190a connecting to the first heavy doping area 150a via the first through hole 163 and the third through hole 181, and to form the drain 190b connecting to the second heavy doping area 150b via the second through hole 164 and the fourth through hole 182.

In step S114, depositing a flat layer 190c on the source 190a and the drain 190b.

In one embodiment, the manufacturing process of the TFTs further includes the steps below.

In step S115, configuring a fifth through hole 191 on the flat layer 190c, and the fifth through hole 191 corresponds to the drain 190b.

In step S116, depositing a transparent conductive layer on the flat layer 190c, and patterning the transparent conductive layer to form the pixel electrode 190d connecting to the drain 190b via the fifth through hole 191. Please refer to FIG. 15 with respect to the steps S109 to S116.

Above are embodiments of the present invention, which does not limit the scope of the present invention. Any modifications, equivalent replacements or improvements within the spirit and principles of the embodiment described above should be covered by the protected scope of the invention.

What is claimed is:

1. A thin film transistor (TFT), comprising:
a substrate;
a low temperature poly-silicon (LTPS) layer arranged close to the substrate;
a first light doping area and a second light doping area arranged on the same layer with the LTPS layer, and are arranged at two opposite ends of the LTPS layer, doping concentrations of symmetrical portions of the first light doping area and the with respect to the LTPS layer are the same;
a first heavy doping area and a second heavy doping area are arranged at the same layer with the LTPS layer, the first heavy doping area is arranged on one end of the first light doping area farther away from the LTPS layer, the doping concentrations of symmetrical portions of the first heavy doping area and the second heavy doping area with respect to the LTPS layer are the same, the second heavy doping area is arranged on one end of the second light doping area farther away from the LTPS layer, doping types of the first light doping area, the second light doping area, the first heavy doping area, and the second heavy doping area are the same;
a first insulation layer comprises a first portion and a second portion, the first portion covers the LTPS layer, the first light doping area, the second light doping area, the first heavy doping area, and the second heavy doping area, the second portion is arranged in a middle portion of a surface of the LTPS layer facing away the LTPS layer, and the second portion and the first portion cooperatively form a “ [symbol] ”-shaped structure; and
a gate is arranged on the second portion, and the gate contacts with the second portion, the gaps respectively between two end surfaces of the gate and a middle point of the LTPS layer are the same.

2. The TFT as claimed in claim 1, wherein the first light doping area contacts with the LTPS layer via a first plane, and the second light doping area contacts with the LTPS layer via a second plane, the second heavy doping area is arranged on one end of the second light doping area facing away the LTPS layer, the second portion comprises a first end surface and a second end surface opposite to the first end surface, the first end surface and the second end surface respectively contacts with the surfaces of the first portion close to the second portion, the first end surface and the first plane are on the same plane, and the second end surface and the second plane are on the same plane.

3. The TFT as claimed in claim 1, wherein the first portion comprises a first through hole corresponding to the first heavy doping area, and a second through hole corresponding to the second heavy doping area, the TFT further comprises:
a second insulation layer covers the gate, and the second insulation layer comprises a third through hole and a fourth through hole, the third through hole communicates with the first through hole, and the fourth through hole communicates with the second through hole;
a source and a drain arranged on the second insulation layer, and the source connects to the first heavy doping area via the first through hole and the third through hole, the drain connects to the second heavy doping area via the second through hole and the fourth through hole; and
a flat layer covers the source and the drain.

4. The TFT as claimed in claim 3, wherein the flat layer comprises a fifth through hole corresponding to the drain, the TFT further includes a pixel electrode arranged on the flat layer, and the pixel electrode connects to the drain via the fifth through hole.

5. The TFT as claimed in claim 1, wherein doping types of the first light doping area, the second light doping area, the first heavy doping area, and the second heavy doping area are N-type ion doping or P-type ion doping.

6. A manufacturing method of TFTs, comprising:
providing a substrate;
forming a polysilicon layer on the substrate and patterning the polysilicon layer to form a LTPS pattern;
forming a gate insulation layer, a first metal layer, and a photo-resist layer on a surface of the LTPS pattern facing away the substrate in sequence;
patterning the first photo-resist layer to reserve a first photo-resist pattern corresponding to the LTPS pattern, the first photo-resist pattern comprises a first surface and a second surface opposite to the first surface, the first surface and the second surface contact with a surface of the first metal layer close to the photo-resist layer, the first surface and the second surface are between two opposite planes of the LTPS pattern contacting with the substrate;
applying the patterning process to the first metal layer to remove the first metal layer uncovered by the first photo-resist pattern, to reserve the first metal layer covered by the first photo-resist pattern, and to etch a portion of the gate insulation layer to reserve the first insulation layer corresponding to the LTPS pattern, the first insulation layer comprises a first portion and a second portion, the first portion covers the LTPS pattern, the second portion is arranged in a middle portion of the surface of the first portion facing away the LTPS layer, and the second portion and the first portion cooperatively form a “ [symbol] ”-shaped structure, the two opposite end surfaces of the second portion are on the same plane respectively with the first surface and the second surface;
applying an ashing process to two ends of the first photo-resist pattern;
applying an etching process to the first metal layer to remove two ends of the ashed areas of the first photo-resist pattern corresponding to the first metal layer, and the reserved first metal layer is formed to be the gate;
adopting the first photo-resist pattern and the first insulation layer as masks to perform an ion doping process to the LTPS pattern, the LTPS pattern corresponding to the first photo-resist pattern is formed to be the LTPS layer, which is only covered by the first portion and the second portion, the portion of the LTPS layer uncovered by the first photo-resist pattern is formed to be the first light doping area and the second light doping area, the LTPS pattern only covered by the first portion is formed to be the first heavy doping area and the second heavy doping area;
applying the etching process to the first insulation layer to remove the portion of the second portion uncovered by the gate; and
stripping the first photo-resist pattern.

7. The manufacturing method of TFTs as claimed in claim 6, wherein the method further comprises:
depositing a second insulation layer on the gate and the first insulation layer;
configuring through holes on the second insulation layer and the first insulation layer, and the through holes correspond to the first heavy doping area and the second heavy doping area,
the first through hole corresponding to the first heavy doping area and the second through hole corresponding to the second heavy doping area are formed on the first insulation layer, and the third through hole communicating with the first through hole and the fourth through hole communicating with the second through hole are formed on the second insulation layer;
depositing a second metal layer on the second insulation layer to pattern the second metal layer so as to form a source connecting to the first heavy doping area via the first through hole and the third through hole, and to form a drain connecting to the second heavy doping area via the second through hole and the fourth through hole; and
depositing a flat layer on the source and the drain.

8. The manufacturing method of TFTs as claimed in claim 6, wherein the ion doping are of N-type ion doping or P-type ion doping.

9. The manufacturing method of TFTs as claimed in claim 6, wherein when the first photo-resist pattern and the first insulation layer are adopted as the masks to perform the ion doping process toward the LTPS pattern, the doping concentrations of the first portion, the second portion, and the first photo-resist pattern are the same, and the doping time are the same.

10. A Complementary Metal Oxide Semiconductor (CMOS) component comprises a TFT, and the TFT comprises:
a substrate;
a low temperature poly-silicon (LTPS) layer arranged close to the substrate;
a first light doping area and a second light doping area arranged on the same layer with the LTPS layer, and are arranged at two opposite ends of the LTPS layer, doping concentrations of symmetrical portions of the first light doping area and the with respect to the LTPS layer are the same;
a first heavy doping area and a second heavy doping area are arranged at the same layer with the LTPS layer, the first heavy doping area is arranged on one end of the first light doping area farther away from the LTPS layer, the doping concentrations of symmetrical portions of the first heavy doping area and the second heavy doping area with respect to the LTPS layer are the same, the second heavy doping area is arranged on one end of the second light doping area farther away from the LTPS layer, doping types of the first light doping area, the second light doping area, the first heavy doping area, and the second heavy doping area are the same;
The first insulation layer comprises a first portion and a second portion, the first portion covers the LTPS layer, the first light doping area, the second light doping area, the first heavy doping area, and the second heavy doping area, the second portion is arranged in a middle portion of a surface of the LTPS layer facing away the LTPS layer, and the second portion and the first portion cooperatively form a “ [symbol] ”-shaped structure; and
a gate is arranged on the second portion, and the gate contacts with the second portion, the gaps respectively between two end surfaces of the gate and a middle point of the LTPS layer are the same.

11. The CMOS component of TFTs as claimed in claim 10, wherein the first light doping area contacts with the LTPS layer via a first plane, and the second light doping area contacts with the LTPS layer via a second plane, the second heavy doping area is arranged on one end of the second light doping area facing away the LTPS layer, the second portion comprises a first end surface and a second end surface opposite to the first end surface, the first end surface and the second end surface respectively contacts with the surfaces of the first portion close to the second portion, the first end surface and the first plane are on the same plane, and the second end surface and the second plane are on the same plane.

12. The CMOS component of TFTs as claimed in claim 10, wherein the first portion comprises a first through hole corresponding to the first heavy doping area, and a second through hole corresponding to the second heavy doping area, the TFT further comprises:
a second insulation layer covers the gate, and the second insulation layer comprises a third through hole and a fourth through hole, the third through hole communicates with the first through hole, and the fourth through hole communicates with the second through hole;
a source and a drain arranged on the second insulation layer, and the source connects to the first heavy doping area via the first through hole and the third through hole, the drain connects to the second heavy doping area via the second through hole and the fourth through hole; and
a flat layer covers the source and the drain.

13. The CMOS component of TFTs as claimed in claim 12, wherein the flat layer comprises a fifth through hole corresponding to the drain, the TFT further includes a pixel electrode arranged on the flat layer, and the pixel electrode connects to the drain via the fifth through hole.

14. The CMOS component of TFTs as claimed in claim 10, wherein doping types of the first light doping area, the second light doping area, the first heavy doping area, and the second heavy doping area are N-type ion doping or P-type ion doping.
